(19) United States
(12) Patent Application Publication
(10) Pub. No.: US 2006/0226772 A1
(43) Pub. Date: Oct. 12, 2006

(54) Increased light output light emitting device using multiple phosphors

(76) Inventors: Kheng Leng Tan, Penang (MY); Su Lin Oon, Penang (MY); Wen Ya Ou, Penang (MY); Azlida Ahmad, Penang (MY)

Correspondence Address: AGILENT TECHNOLOGIES INC.;INTELLECTUAL PROPERTY ADMINISTRATION, LEGAL DEPT,, M/S DU404, P.O. BOX 7599, LOVELAND, CO, 80537-0599, US

(21) Appl. No.: 11/100,021

(22) Filed: Apr. 6, 2005

(51) Int. Cl. C09K 11/02; H01L 33/00; H05B 33/00

(52) U.S. Cl. 313/512; 252/301.36; 252/301.6 S; 252/301.4 S; 313/485; 257/98; 257/100

(57) ABSTRACT

A method for producing a light emitting device using two phosphors dispersed homogenously in a host matrix. The host matrix may be a polymer, such as heat and/or UV curable epoxy, silica glass, silica gel, silicone, etc. A dispersant, preferably inorganic, is applied to the host matrix to create a strong and stable three dimensional network within the host matrix. The BGS and ZnSeS phosphors are trapped equally in the three dimensional network, holding them homogenously in place within the host matrix. In one embodiment, the inorganic dispersant can be a hydrophobic formed silica, such as, for example, R812.

### BACKGROUND

Electronic solid-state light sources typically use a population of phosphor particles disposed in a host matrix. Typically, these phosphors are Barium Gallium Sulfide (BGS-green) having a mean particle size of 25 μm and specific gravity of 3.8 and Zinc Selenium Sulfide (ZnSeS-orange) having a mean particle size of 25 μm and specific gravity of 4.6. ZnSeS, because of its higher specific gravity, settles faster than does BGS. This settling causes a drop in the white light conversion efficiency of the device. After settlement the luminous intensity (Iv) is only 1.2 candela (cd) and flux only 0.68 lumen (lm) and thus not sufficient for many light emitting diode applications, such as automotive, mobile, illumination, etc.

One current method of suspending the phosphor (to reduce settling) is by coating the phosphor with a material having an affinity for the host matrix. One example of a coating material is an adhesion promoter. Adhesion promoters are also added to the host matrix to help suspend the phosphor. Another method of suspending the phosphor is by using a high viscosity host matrix to create resistance to the movement of the phosphor particles through the host matrix. This high viscosity reduces the rate of sedimentation of the phosphor particles.

For a variety of reasons these prior art methods of suspending the phosphor are not effective on large particle size and high specific gravity phosphors, especially the ZnSeS phosphor, mainly because the phosphor coating material is not strong enough to hold the phosphor in the host matrix due to the gravitational pull on such high specific gravity phosphors. Similarly, resistance through the high viscosity host matrix does not hold the high specific gravity phosphors in the host matrix over time.

In summary then, in a two-phosphor system, both of the phosphors must work together in a certain ratio to convert the color of the light coming from the solid state light source to a desired color, usually white. The ineffective phosphor suspension method of the prior art allowed the ZnSeS phosphor, particles with higher specific gravity to settle faster than did the BGS phosphor particles with lower specific gravity. Consequently, to achieve the desired intensity of light output a high phosphor loading is needed to counteract the settling phenomena in order to convert a high percentage of the primary light to secondary light.

### BRIEF SUMMARY

One embodiment shows a method for producing a light emitting device using two phosphors dispersed homogenously in a host matrix. The host matrix may be a polymer, such as heat and/or UV curable epoxy, silica glass, silica gel, silicone, etc. A dispersant, preferably inorganic, is applied to the host matrix to create a strong and stable three dimensional network within the host matrix. The BGS and ZnSeS phosphors are trapped equally in the three dimensional network, holding them homogenously in place within the host matrix. In one embodiment, the inorganic dispersant can be a hydrophobic formed silica, such as, for example, R812.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows one embodiment of a light device using the concepts of this invention;

FIG. 2 shows the light device of FIG. 1 mounted on a substrate; and

FIG. 3 shows a light device without a reflector.

### DETAILED DESCRIPTION

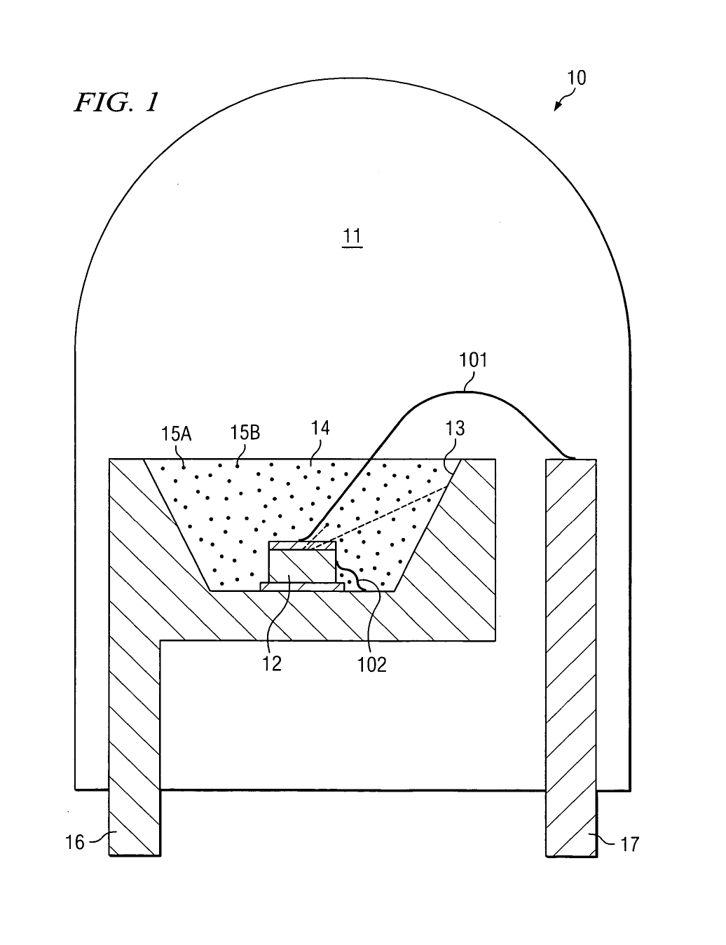

FIG. 1 shows one embodiment of light device 10 having light source 12 contained within deflector 13 surrounded by outer lens 11. Power to light source 12 is via terminals 16 and 17 and connector wires 101 and 102. Phosphors 15A and 15B are contained in host 14 within reflector 13. The host can be a polymer, such as heat and/or UV curable epoxy, silica glass, silica gel, silicon, etc. An inorganic dispersant, such as, for example R812 in a concentration of 10%, is added to the host to form a three dimensional structure within the host. The BGS and ZnSeS phosphor particles are then introduced into the host.

The phosphor particles are then stirred together with the host until the phosphors are homogeneously dispersed in the host. This mixture is then cured to form the solid host with the homogeneously dispersed phosphors therein. In one embodiment, the mixture is cured at a temperature of 140° C. for a period of 2 hours.

Note that the mixing and/or curing can occur within device 10 and/or can occur separately and formed to fit into reflector 13. Also note that the phosphors can be mixed in different ratios if desired.

In FIG. 1, phosphor particles 15A and 15B are homogeneously mixed. These phosphor particles are BGS and ZnSeS phosphors, but can be any phosphors and, in fact, can be more than two phosphors if desired. The nature of the final product is that the phosphors are stabilized and thus do not migrate out of the host and thereby retain their initial illuminance.

The homogeneously suspended phosphors improve the optical performance of the light emitting device since more controlled color mixing is achieved than is achieved with previous systems. The brightness of the device will also be improved as all the incident light is captured and converted by the phosphors suspended in the cured matrix to produce the secondary light. In one example, the Iv increased by 15% from 1.2 cd to 1.4 cd and the flux increased by 45% from 0.68 lm to 1 lm and little, if any phosphor settling was observed.

If desired other materials can be added into the host matrix either prior to curing or thereafter to achieve additional advantages. For example, an adhesion promoter can be added to promote adhesion of the host matrix to other surfaces such as to the diffuser surface of the illumination device. Another example would be a UV inhibitor that would be added to increase the resistance of the host matrix to breakdown due to UV light impacting the host matrix. Another additive can be an oxidation stabilizer to enable the host matrix to resist breakdown due to heat of the lamp. Examples of adhesion promoters are Elvaloy from DuPont Polymer Modifiers, Silquest from GE Silicones and Lotader from Arkema, examples of UV inhibitors are Chimassorb and Tinuvin from Ciba Specialty Chemicals and Baerostab from Baerlocher and an example of an oxidation stabilizer is Irgastab from Ciba Specialty Chemicals.

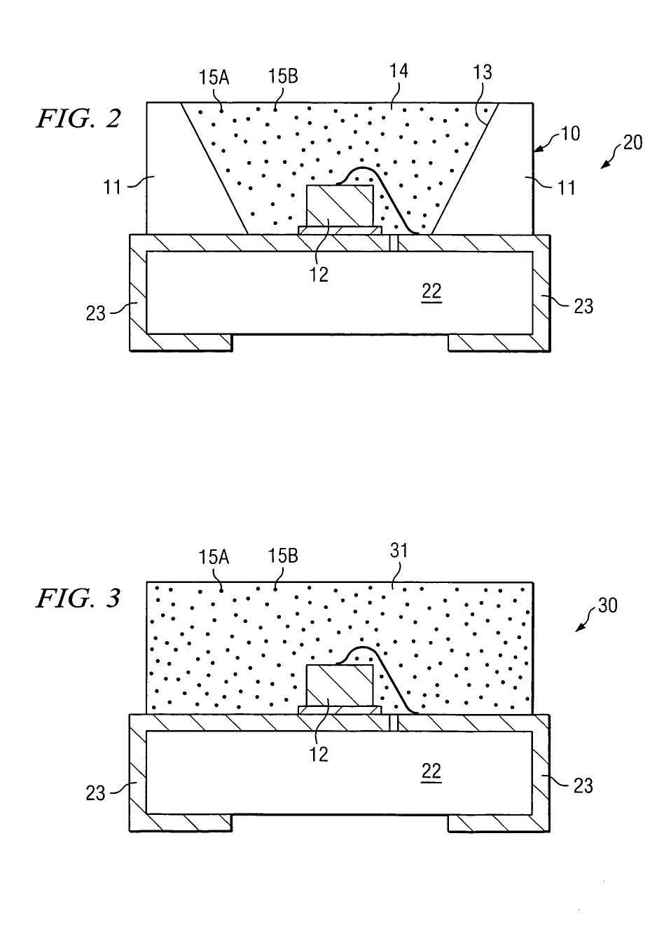

FIG. 2 shows light device 10 mounted on substrate 22 by bracket 23 to form display 20. Display 20 would typically comprise a plurality of devices 10, not all of which need have the same ratio of phosphors.

FIG. 3 shows an alternative embodiment 30 where reflector 13 of device 10 (FIG. 1) has been removed.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. The method of making a light changing medium for a light emitting device, said method comprising:
creating a host medium in uncured form;
adding a dispersant into said host medium to create a three-dimensional structure within said host medium;
mixing into said three-dimensional structure particles of at least two radiant materials, and
curing said mixture.

2. The method of claim 1 wherein said radiant material comprises phosphor particles having different specific gravities.

3. The method of claim 2 wherein said phosphor particles comprise BGS and ZnSeS phosphors.

4. The method of claim 1 wherein said host medium is a polymer.

5. The method of claim 4 wherein said polymer is cured by at least one of the following: heat, UV.

6. The method of claim 1 wherein said dispersant comprises a 10% mixture of R812.

7. The method of claim 1 further comprising:
positioning said cured host around a light emitting source such that light color from said source is modified by said two radiant materials within said cured host.

8. The method of claim 7 wherein said light emitting source is a LED.

9. The method of claim 1 wherein said dispersant is inorganic.

10. The method of claim 1 further comprising:
adding at least one of the following to said mixture: adhesion promoter, UV inhibitor, oxidation stabilizer.

11. The method of claim 1 further comprising:
adding a UV inhibitor to said mixture.

12. A lamp comprising:
a light source within said lamp;
at least one contained area around said light source within said lamp, said contained area comprising a stabilized mixture of at least two phosphors in particle form, said phosphors having different specific gravities and operative for modifying the color of the light from said light source.

13. The method of claim 10 wherein said stabilized mixture comprises:
a polymer having a three dimensional structure created therein and wherein said phosphors have been cured within said structure.

14. The method of claim 13 wherein said phosphors within said structure are mixed so as to become, and remain, homogeneous.

15. The method of claim 14 wherein said structure is created by introducing an inorganic dispersant into said polymer when said polymer is in an uncured state.

16. The method of claim 13 wherein said phosphors are BGS and ZnSeS particles having a mean particle size in the range of 25 μm.

17. A light emitting device comprising:
a light source; and
means for surrounding at least a portion of said light source with a stabilized homogeneous mixture of BGS and ZnSeS phosphors, said phosphors having a mean particle size in the range of 25 μm.

18. The device of claim 17 wherein said surrounding means comprising:
material mixed with said phosphors therein prior to being cured.

19. The device of claim 18 further comprising:
means for controlling the color of light produced from said light emitting device by adjusting the proportion of the respective phosphors.

20. The device of claim 18 wherein said curable material is a polymer selected from the list of: silica gel, silica glass, silicone, epoxy.

21. The device of claim 20 wherein said polymer is cured by at least one of: heat, UV.
